(19) United States
(12) Patent Application Publication
(10) Pub. No.: US 2020/0211861 A1
(43) Pub. Date: Jul. 2, 2020

(54) DIE BONDING PROCESS FOR MANUFACTURING SEMICONDUCTOR DEVICE AND SEMICONDUCTOR DEVICE MANUFACTURED THEREBY

(71) Applicant: XIAMEN SAN'AN OPTOELECTRONICS CO., LTD., Xiamen (CN)

(72) Inventors: Feng WANG, Xiamen (CN); Wanjun CHEN, Xiamen (CN); Su-Hui LIN, Xiamen (CN); Ling-Yuan HONG, Xiamen (CN); Quan LIN, Xiamen (CN); Yu ZHAN, Xiamen (CN); Chen-Ke HSU, Xiamen (CN)

(21) Appl. No.: 16/816,108

(22) Filed: Mar. 11, 2020

Related U.S. Application Data
(63) Continuation of application No. PCT/CN2018/085130, filed on Apr. 28, 2018.

(30) Foreign Application Priority Data
Sep. 13, 2017 (CN) 201710822522.3
Sep. 13, 2017 (CN) 201710823265.5

(51) Int. Cl. H01L 21/48; H01L 21/52; H01L 21/56; H01L 25/00; H01L 25/16; H01L 33/48; H01L 33/56

(52) U.S. Cl. CPC H01L 21/4846; H01L 21/52; H01L 21/56; H01L 33/56; H01L 25/167; H01L 33/486; H01L 25/50

(57) ABSTRACT

A die bonding process for manufacturing a semiconductor device includes the steps of: a) preparing a semiconductor structure and a substrate, b) mounting an electrode structure on the semiconductor structure to form a semiconductor component, c) forming a protective component at a die bonding region, and d) mounting the semiconductor component on the substrate via a die bonding technique. The protective component is made of an adsorbent material which has a greater adsorption capability for a suspended pollutant around the semiconductor device than an adsorption capability for the suspended pollutant of a material for the electrode structure.

### CROSS-REFERENCE TO RELATED APPLICATION

This application is a bypass continuation-in-part application of International Application No. PCT/CN2018/085130 filed on Apr. 28, 2018, which claims priority of Chinese Patent Application Nos. 201710822522.3 and 201710823265.5, both filed on Sep. 13, 2017. The entire content of each of the international and Chinese patent applications is incorporated herein by reference.

### FIELD

The disclosure relates to a die bonding process, and more particularly to a die bonding process for manufacturing a semiconductor device. The disclosure also relates to a semiconductor device and a semiconductor light-emitting device.

### BACKGROUND

With continuous mining of performance of semiconductor components, the manufacture of the semiconductor components has become one of the most valued fields recently. In the manufacturing process for the semiconductor components, a gold (Au) material is a preferred material for a top layer of an electrode structure of a semiconductor chip due to its soft texture, stable property, and good current spreading effect, and is commonly used in the art. However, the weak interaction of Au—Au bonding may lead to a cyclic high nuclear cluster compound layer being adsorbed on a surface of the electrode structure. Therefore, when the semiconductor chip is present in an environment containing organic materials, the gold material contained in the semiconductor chip may be a medium that subjects epoxy silane-based organic materials to polycondensation and curing on a surface of the gold material, resulting in pollution of a pad electrode, such that abnormalities in wire bonding, inter-metallic joining, and the like may occur during a die bonding process for the semiconductor ship. Therefore, the qualities of the semiconductor components manufactured thereby may be adversely affected.

Referring to FIG. 1, light-emitting diode (LED) components are subjected to further procedures, such as inversion, separation, and transportation after being manufactured. During such procedures, the wire bonding regions (i.e., the pad electrodes) of the LED components are exposed to atmosphere. The pollutants contained in the atmosphere may adsorb on surfaces of the pad electrodes, causing primary pollution of the pad electrodes. During subsequent packaging, the LED components are subjected to further procedures, such as die bonding using a die bond paste and heating to cure the die bond paste. During the heating to cure the die bond paste, some low reactive molecules (such as SiH₄) contained in the die bond paste are easily transferred to the primarily polluted electrodes, resulting in further pollution of the electrodes by organic pollutants. Therefore, the wire bonding procedure is not implemented effectively, which adversely affects application of the thus manufactured LED components.

### SUMMARY

An object of the disclosure is to use an adsorbent material, which has a greater adsorption capability for suspended pollutants (for example, aerosol-type pollutants and dust-type pollutants) than an adsorption capability for the suspended pollutants of electrodes, in a die bonding process for manufacturing a semiconductor device so as to overcome the aforesaid shortcomings of the prior art.

Another object of the discourse is to provide a semiconductor light-emitting device which includes an adsorbent material having a greater adsorption capability for suspended pollutants (for example, aerosol-type pollutants and dust-type pollutants) than an adsorption capability for the suspended pollutants of electrodes, so as to overcome the aforesaid shortcomings of the prior art

According to a first aspect of the disclosure, there is provided a die bonding process for manufacturing a semiconductor device, which includes the steps of:

a) preparing a semiconductor structure and a substrate;

b) mounting an electrode structure on the semiconductor structure to form a semiconductor component;

c) forming a protective component at a die bonding region which is located on at least one selected from the group consisting of the semiconductor structure and the substrate; and

d) mounting the semiconductor component on the substrate via a die bonding technique to obtain the semiconductor device,

wherein the protective component is made of an adsorbent material which has a greater adsorption capability for a suspended pollutant around the semiconductor device than an adsorption capability for the suspended pollutant of a material for the electrode structure.

According to a second aspect of the disclosure, there is provided a semiconductor device which includes a substrate, a semiconductor component, a die bond paste, and a protective component. The semiconductor component is formed on the substrate, and includes a semiconductor structure and an electrode structure formed on the semiconductor structure. The die bond paste is sandwiched between the substrate and the semiconductor component so as to bond the semiconductor component to the substrate. The protective component is made of an adsorbent material which has a greater adsorption capability for a suspended pollutant including a pollutant material produced from the die bond paste and suspended particles than an adsorption capability for the suspended pollutant of the electrode structure.

According to a third aspect of the disclosure, there is provided a semiconductor light-emitting device which includes a semiconductor component and an adsorbent material.

The semiconductor component includes a laminate structure and an electrode structure.

The laminate structure includes a first conductive semiconductor layer, a second conductive semiconductor layer, and an electrode structure. The light-emitting layer is formed on the first conductive semiconductor layer. The second conductive semiconductor layer is formed on the light-emitting layer and has a conductivity type different from that of the first conductive semiconductor layer.

The electrode structure is formed on at least one selected from the group consisting of the first conductive semiconductor layer and the second conductive semiconductor layer. The laminate structure has a non-electrode region which is located on at least one selected from the group consisting of the first conductive semiconductor layer and the second conductive semiconductor layer and which is not provided with the electrode structure thereon.

The adsorbent material is disposed at the non-electrode region and has a greater adsorption capability for a pollutant than an adsorption capability for the pollutant of the electrode structure so as to inhibit the electrode structure from adsorbing the pollutant.

### BRIEF DESCRIPTION OF THE DRAWINGS

Other features and advantages of the disclosure will become apparent in the following detailed description of the embodiments with reference to the accompanying drawings, of which:

FIG. 1 is a schematic view illustrating primary pollution and low reactive molecule adsorption on pad electrodes of a conventional semiconductor light-emitting component;

FIG. 2 is a flow diagram of a die bonding process for manufacturing a semiconductor device according to the disclosure;

FIG. 3 is a schematic view of a first embodiment of a semiconductor device according to the disclosure;

FIG. 4 is a schematic view of a second embodiment of a semiconductor device according to the disclosure;

FIG. 5 is a schematic view of a third embodiment of a semiconductor device according to the disclosure;

FIG. 6 is a schematic view of a fourth embodiment of a semiconductor device according to the disclosure;

FIG. 7 is a schematic view of a fifth embodiment of a semiconductor device according to the disclosure;

FIG. 8 is a schematic view of a sixth embodiment of a semiconductor device according to the disclosure; and

FIG. 9 is a schematic view of a seventh embodiment of a semiconductor device according to the disclosure.

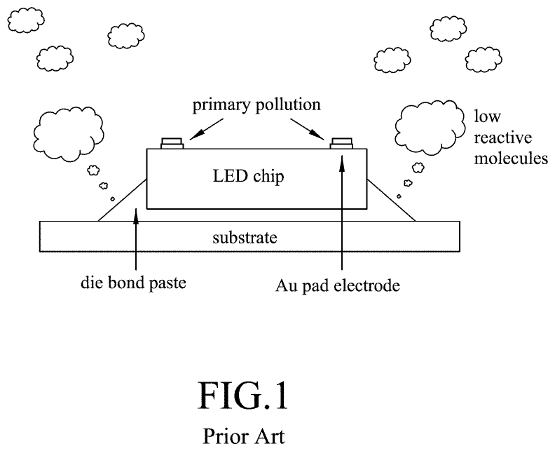

### DETAILED DESCRIPTION

Before the disclosure is described in greater detail, it should be noted that some components are exaggeratedly shown in the figures for the purpose of convenient illustration and are not in scale.

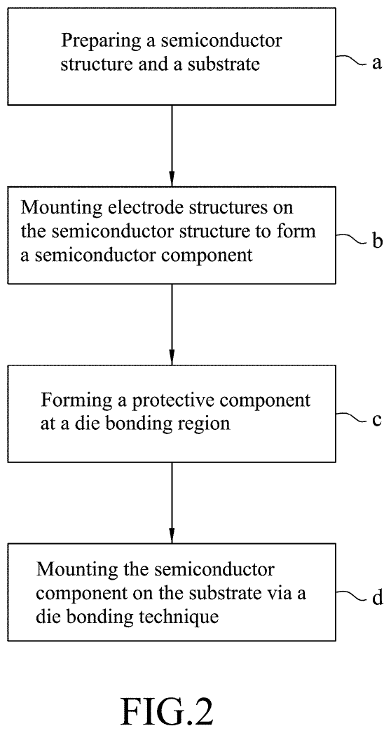

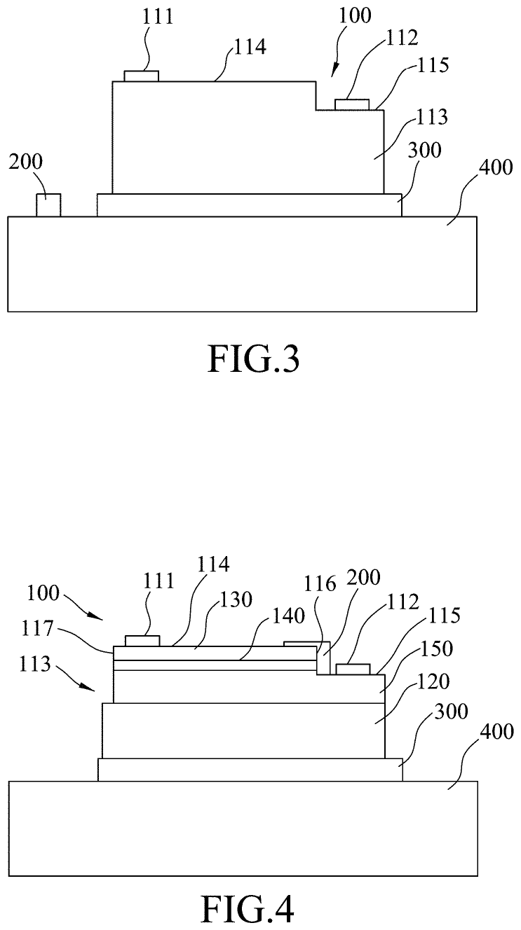

Referring to FIGS. 2 and 3, a die bonding process for manufacturing a semiconductor device according to the disclosure includes the steps of:

a) preparing a semiconductor structure 113 and a substrate 400 (for example, a packaging substrate);

b) mounting electrode structures 111, 112 on the semiconductor structure 113 to form a semiconductor component 100;

c) forming a protective component 200 at a die bonding region which is located on at least one selected from the group consisting of the semiconductor structure 113 and the substrate 400; and

d) mounting the semiconductor component 100 on the substrate 400 via a die bonding technique to obtain the semiconductor device.

The protective component 200 is made of an adsorbent material which has a greater adsorption capability for a suspended pollutant around the semiconductor device than an adsorption capability for the suspended pollutant of a material for the electrode structure 111, 112.

Referring specifically to FIG. 2, in the first embodiment of the semiconductor device according to the disclosure, the die bonding region is located on the substrate 400. In other words, in step c) of the die bonding process for manufacturing the first embodiment of the semiconductor device according to the disclosure, the protective component 200 is formed on the substrate 400.

In certain embodiments, in step d) of the die bonding process according to the disclosure, the die bonding technique is implemented by fixing the semiconductor component 100 to the substrate 400 using a die bond paste 300 and heating to cure the die bond paste 300. In certain embodiments, the die bond paste 300 is heated at a temperature ranging from 100° C. to 200° C. so as to remove solvent contained in the die bond paste 300 and to cure the die bond paste 300.

In certain embodiments, the suspended pollutant includes a pollutant material produced from the die bond paste 300 and suspended particles (not shown) present around the semiconductor device. Specifically, the pollutant material is usually produced from the die bond paste 300 during heating of the die bond paste 300, and is present in an aerosol form.

In certain embodiments (for example, the embodiments shown in FIGS. 4 to 6, which will be described in details hereinafter), in step c) of the die bonding process according to the disclosure, the semiconductor structure 113 has a side wall portion, and the protective component 200 is formed on the side wall portion of the semiconductor structure 113.

In certain embodiments, in step c) of the die bonding process according to the disclosure, the protective component 200 is formed to permit the protective component 200 to be spaced apart from the electrode structures 111, 112 by a distance of less than 300 mm. When the distance between the protective component 200 and the electrode structures 111, 112 is more than 300 mm, the effect of inhibiting the electrode structures 111, 112 from adsorbing the pollutant may be reduced.

In certain embodiments, in step b) of the die bonding process according to the disclosure, the electrode structures 111, 112 are made of a conductive material independently selected from the group consisting of gold, aluminum, silver, titanium, and combinations thereof.

In certain embodiments, in step c) of the die bonding process according to the disclosure, the protective component 200 may be selected from the group consisting of an activated carbon, a porous ceramic, an adsorptive organic compound, a fiber material, a nanostructured insulation oxide, and combinations thereof.

In certain embodiments, in step a) of the die bonding process according to the disclosure, the semiconductor component 100 may be selected from the group consisting of a light-emitting diode, a solar cell, an integrated circuit, and combinations thereof.

Referring again to FIG. 2, the first embodiment of a semiconductor device according to the disclosure includes the substrate 400, the semiconductor component 100, the die bond paste 300, and the protective component 200.

The semiconductor component 100 is formed on the substrate 400, and includes the semiconductor structure 113 and the electrode structures 111, 112 formed on the semiconductor structure 113. Specifically, in the first embodiment, the electrode structures 111, 112 are specified as a first electrode structure 111 and a second electrode structure 112, respectively, which are disposed on an upper surface portion 114 and a lower surface portion 115 of the semiconductor structure 113, respectively.

As described above, the semiconductor component 100 may be selected from the group consisting of a light-emitting diode, a solar cell, an integrated circuit, and combinations thereof.

The die bond paste 300 is sandwiched between the substrate 400 and the semiconductor component 100 so as to bond the semiconductor component 100 to the substrate 400.

The protective component 200 is made of an adsorbent material which has a greater adsorption capability for a suspended pollutant including a pollutant material produced from the die bond paste 300 and suspended particles than an adsorption capability for the suspended pollutant of the electrode structures 111, 112.

In certain embodiments, the protective component 200 is formed on at least one selected from the group consisting of the substrate 400 and the semiconductor structure 113. Specifically, in the first embodiment, the protective component 200 is formed on the substrate 400. As described above, the protective component 200 may be selected from the group consisting of an activated carbon, a porous ceramic, an adsorptive organic compound, a fiber material, a nanostructured insulation oxide, and combinations thereof.

In certain embodiments, the semiconductor structure 113 is a light-emitting diode having a light-emitting surface, and the protective component 200 is not formed on the light-emitting surface of the light-emitting diode.

Referring to FIG. 4, a second the embodiment of a semiconductor device according to the disclosure is similar to the first embodiment except for the following differences.

In the second embodiment, the semiconductor structure 113 is a light-emitting diode having a face-up structure, which includes a backing layer 120, an n-type layer 150 disposed on the backing layer 120, a light-emitting layer 140 disposed on the n-type layer 150, and a p-type epitaxial layer 130 disposed on the light-emitting layer 140.

The first and second electrode structures 111, 112 are disposed on a top surface of the p-type epitaxial layer 130 and a top surface of the n-type layer 150 not covered by the light-emitting layer 140, respectively.

The semiconductor structure 113 has a first side wall portion 116 proximate to the second electrode structure 112 and a second side wall portion 117 proximate to the first electrode structure 111. The protective component 200 is formed on first side wall portion 116. The porous ceramic, such as a silicate ceramic may be used as the protective component 200 to prevent abnormality (for example, short circuit) of the p-type epitaxial layer 130 and to adsorb the pollutant during the die bonding process.

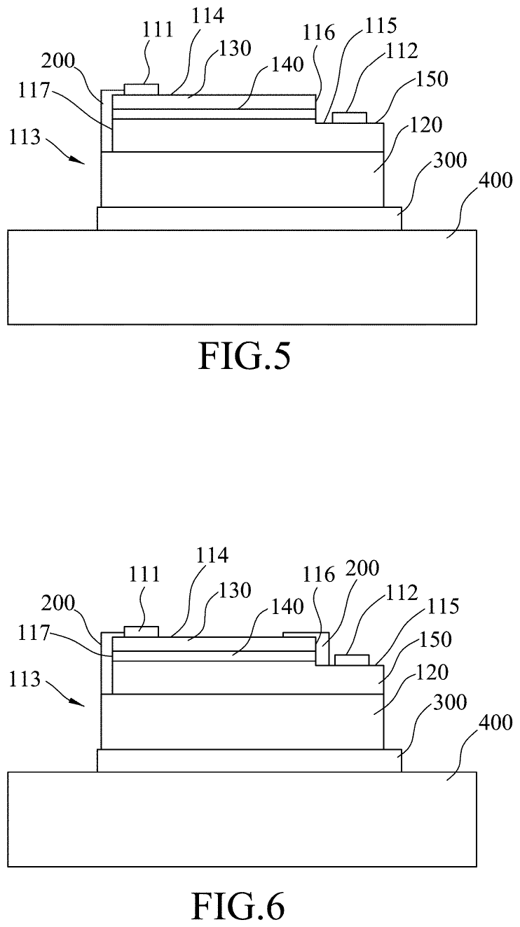

Referring to FIG. 5, a third embodiment of a semiconductor device according to the disclosure is similar to the second embodiment except that in the third embodiment, the protective component 200 is formed on the second side wall portion 117. Since the die bond paste 300 is disposed below the semiconductor structure 113 and the protective component 200 is formed between the die bond paste 300 and the first electrode structure 111, the protective component 200 can more effectively inhibit the first electrode structure 111 from adsorbing the pollutant so as to significantly decrease abnormalities in wire bonding, inter-metallic joining, and the like, compared to the second embodiment.

Referring to FIG. 6, a fourth embodiment of a semiconductor device according to the disclosure is similar to the second embodiment except that in the fourth embodiment, the protective component 200 is formed on each of the first and second side wall portions 116, 117. Therefore, the first and second electrode structures 111, 112 can be further inhibited more effectively from adsorbing the pollutant. In addition, insulation protection for the semiconductor structure 113 can be achieved by forming the protective component 200, which is made of an insulating absorbent material, on each of the first and second side wall portions 116, 117.

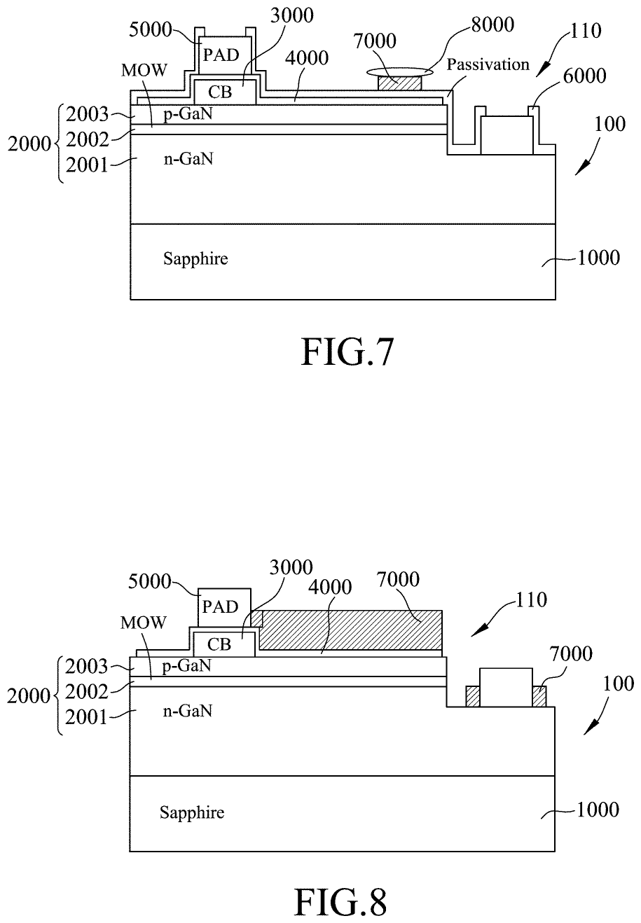

Referring to FIG. 7, a fifth embodiment of a semiconductor device according to the disclosure is specifically a nitride semiconductor light-emitting device which includes a substrate 1000 (for example, a sapphire substrate), a semiconductor component 100, and an adsorbent material 7000.

The semiconductor component 100 includes a semiconductor structure 110 and an electrode structure 5000.

The semiconductor structure 110 may be a light-emitting diode, a laser diode, and includes a laminate structure 2000, a current blocking layer 3000, a current spreading layer 4000, and an insulating protective layer 6000.

The laminate structure 2000 includes a first conductive semiconductor layer 2001 (such as an n-type layer, for example, a n-GaN layer) disposed on the substrate 1000, a light-emitting layer 2002 (for example, a multiple quantum well (MQW) layer) formed on the first conductive semiconductor layer 2001, and a second conductive semiconductor layer 2003 (such as a p-type layer, for example, a p-GaN layer), which is formed on the light-emitting layer 2002 and which has a conductivity type different from that of the first conductive semiconductor layer 2001. Alternatively, if the p-type layer is used as the first conductive semiconductor layer 2001, then the n-type layer is used as the second conductive semiconductor layer 2003.

The current blocking layer 3000 is disposed on the second conductive semiconductor layer 2003.

The current spreading layer 4000 can be formed on at least one selected from the group consisting of the first conductive semiconductor layer 2001 and the second conductive semiconductor layer 2003. Specifically, in the fifth embodiment, the current spreading layer 4000 is disposed on the current blocking layer 3000 and the second conductive semiconductor layer 2003. The current spreading layer 4000 can be made of a metal oxide material selected from the group consisting of indium tin oxide (ITO), zinc oxide (ZnO), cadmium tin oxide (CTO), indium oxide (InO), indium-doped zinc oxide (In-doped ZnO), aluminum-doped zinc oxide (Al-doped ZnO), gallium-doped zinc oxide (Ga-doped ZnO), and combinations thereof.

The insulating protective layer 6000 may be formed on at least one selected from the group consisting of the first conductive semiconductor layer 2001 and the second conductive semiconductor layer 2003.

The electrode structure 5000 (for example, a pad electrode) is formed on at least one selected from the group consisting of the first conductive semiconductor layer 2001 and the second conductive semiconductor layer 2003. Specifically, in the fifth embodiment, the electrode structure 5000 is formed on an exposed portion of the first conductive semiconductor layer 2001 and/or on the current spreading layer 4000. In addition, the laminate structure 2000 has a non-electrode region which is located on at least one selected from the group consisting of the first conductive semiconductor layer 2001 and the second conductive semiconductor layer 2003 and which is not provided with the electrode structure 5000 thereon.

The adsorbent material 7000 is disposed at the non-electrode region and has a greater adsorption capability for a pollutant 8000 than an adsorption capability for the pollutant 8000 of the electrode structure 5000, so as to inhibit the electrode structure 5000 from adsorbing the pollutant 8000. Specifically, in the fifth embodiment, the adsorbent material 7000 is disposed on the insulating protective layer 6000. Alternatively, the adsorbent material 7000 may be disposed below the insulating protective layer 6000. In the fifth embodiment, the insulating protective layer 6000 is formed for protecting the semiconductor component 100 exclusive of the electrode structure 5000, which is exposed from the insulating protective layer 6000. The adsorbent material 7000 is then disposed on the insulating protective layer 6000 (i.e., the non-electrode region) by a technique such as spin-coating, deposition, or a combination thereof. Examples of deposition include physical vapor deposition (for example, evaporation deposition or sputter deposition), chemical vapor deposition, electroplating, and chemical plating deposition, but are not limited thereto. The insulating protective layer 6000 may be made of a metal oxide material selected from the group consisting of silicon oxide (SiO₂), silicon nitride (Si₃N₄), aluminum oxide, (Al₂O₃), titanium oxide (TiO₂) and combinations thereof. Specifically, the protective layer 6000 is made of silicon oxide (SiO₂).

In certain embodiments, the adsorbent material 7000 is formed with a thickness ranging from 1 nm to 100 nm, and is configured as a continuous structure or a patterned structure. In the fifth embodiment, the adsorbent material 7000 is configured as the patterned structure.

In certain embodiments, the adsorbent material 7000 is selected from the group consisting of a metal material, a nano-oxide material, a graphene, an activated carbon, and combinations thereof. In the fifth embodiment, the metal material is used as adsorbent material 7000. Examples of the metal material include hydrogen storage metals or alloys containing at least one selected from the group consisting of Pd, LaNi₅, NdNi₅, CaNi₅, TiNi₅, LaAl₅, LaFe₅, LaCr₅, LaCu₅, LaSi₅, LaSn₅, FeTi, MnTi, CrTi, TiCu, MgZn₂, MgZn₂, NiMg₂, ZrCr₂, ZrMn₂, and combinations thereof.

As described above, since the adsorbent material 7000 has a greater adsorption capability for the pollutant 8000 than an adsorption capability for the pollutant 8000 of the electrode structure 5000, the pollutant 8000 (such as the pollutant present in the primary pollution and the low reactive molecule) can be adsorbed effectively on the adsorbent material 7000, rather than on the electrode structure 5000. Therefore, the aforesaid shortcomings of the prior art can be overcome and the reliability of the semiconductor device thus manufactured can be enhanced.

Referring to FIG. 8, a sixth embodiment of a semiconductor device according to the disclosure is similar to the fifth embodiment except for the following differences. In the sixth embodiment, the adsorbent material 7000 is disposed on the first conductive semiconductor layer 2001 and the current spreading layer 4000, followed by forming an insulating protective layer. In addition, the adsorbent material 7000 in the sixth embodiment is a graphene, which is electrically conductive and is electrically connected to the electrode structure 5000 and configured as a finger for the electrode structure 5000, so as to reduce the negative effect of the adsorbent material 7000 on the brightness of the light emitted from the semiconductor light-emitting device.

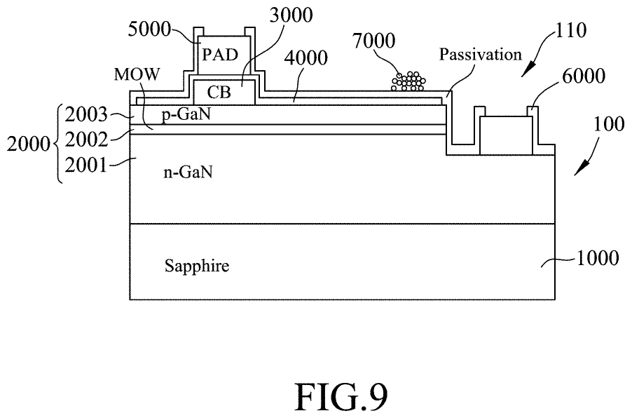

Referring to FIG. 9, a seventh embodiment of a semiconductor device according to the disclosure is similar to the fifth embodiment except that in the seventh embodiment, the adsorbent material 7000 is the nano-oxide material which is selected from the group consisting of ZrO₂, CuO, TiO₂, Al₂O₃, and combinations thereof.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A die bonding process for manufacturing a semiconductor device, comprising the steps of:
a) preparing a semiconductor structure and a substrate;
b) mounting an electrode structure on the semiconductor structure to form a semiconductor component;
c) forming a protective component at a die bonding region which is located on at least one selected from the group consisting of the semiconductor structure and the substrate; and
d) mounting the semiconductor component on the substrate via a die bonding technique to obtain the semiconductor device,
wherein the protective component is made of an adsorbent material which has a greater adsorption capability for a suspended pollutant around the semiconductor device than an adsorption capability for the suspended pollutant of a material for the electrode structure.

2. The die bonding process according to claim 1, wherein in step d), the die bonding technique is implemented by fixing the semiconductor component to the substrate using a die bond paste and heating to cure the die bond paste.

3. The die bonding process according to claim 2, wherein the die bond paste is heated at a temperature ranging from 100° C. to 200° C.

4. The die bonding process according to claim 1, wherein the suspended pollutant includes a pollutant material produced from the die bond paste and suspended particles present around the semiconductor device.

5. The die bonding process according to claim 1, wherein in step c), the protective component is formed on the substrate.

6. The die bonding process according to claim 1, wherein in step c), the semiconductor structure has a side wall portion, and the protective component is formed on the side wall portion of the semiconductor structure.

7. The die bonding process according to claim 1, wherein in step c), the protective component is formed to permit the protective component to be spaced apart from the electrode structure by a distance of less than 300 mm.

8. The die bonding process according to claim 1, wherein in step b), the electrode structure is made of a conductive material selected from the group consisting of gold, aluminum, silver, titanium, and combinations thereof.

9. The die bonding process according to claim 1, wherein in step c), the protective component is selected from the group consisting of an activated carbon, a porous ceramic, an adsorptive organic compound, a fiber material, a nanostructured insulation oxide, and combinations thereof.

10. The die bonding process according to claim 1, wherein in step a), the semiconductor component is selected from the group consisting of a light-emitting diode, a solar cell, an integrated circuit, and combinations thereof.

11. A semiconductor device, comprising:
a substrate;
a semiconductor component formed on said substrate, and including a semiconductor structure and an electrode structure formed on said semiconductor structure;
a die bond paste sandwiched between said substrate and said semiconductor component so as to bond said semiconductor component to said substrate; and
a protective component made of an adsorbent material which has a greater adsorption capability for a suspended pollutant including a pollutant material produced from said die bond paste and suspended particles than an adsorption capability for the suspended pollutant of said electrode structure.

12. The semiconductor device according to claim 11, wherein said protective component is formed on at least one selected from the group consisting of said substrate and said semiconductor structure.

13. The semiconductor device according to claim 11, wherein said protective component is selected from the group consisting of an activated carbon, a porous ceramic, an adsorptive organic compound, a fiber material, a nanostructured insulation oxide, and combinations thereof.

14. The semiconductor device according to claim 11, wherein said semiconductor component is selected from the group consisting of a light-emitting diode, a solar cell, an integrated circuit, and combinations thereof.

15. The semiconductor device according to claim 14, wherein said semiconductor structure is said light-emitting diode having a light-emitting surface, and said protective component is not formed on said light-emitting surface of said light-emitting diode.

16. A semiconductor light-emitting device, comprising:
a semiconductor component including:
a semiconductor structure including:
a laminate structure including:
a first conductive semiconductor layer,
a light-emitting layer formed on said first conductive semiconductor layer, and
a second conductive semiconductor layer which is formed on said light-emitting layer and which has a conductivity type different from that of said first conductive semiconductor layer, and
an electrode structure formed on at least one selected from the group consisting of said first conductive semiconductor layer and said second conductive semiconductor layer, said laminate structure having a non-electrode region which is located on at least one selected from the group consisting of said first conductive semiconductor layer and said second conductive semiconductor layer and which is not provided with said electrode structure thereon; and
an adsorbent material disposed at said non-electrode region and having a greater adsorption capability for a pollutant than an adsorption capability for the pollutant of the electrode structure so as to inhibit said electrode structure from adsorbing said pollutant.

17. The semiconductor light-emitting device according to claim 16, wherein said adsorbent material is electrically conductive, and is electrically connected to said electrode structure and configured as a finger for said electrode structure.

18. The semiconductor light-emitting device according to claim 16, wherein said adsorbent material is formed with a thickness ranging from 1 nm to 100 nm.

19. The semiconductor light-emitting device according to claim 16, wherein said adsorbent material is configured as a structure selected from the group consisting of a continuous structure and a patterned structure.

20. The semiconductor light-emitting device according to claim 16, wherein said adsorbent material is disposed at said non-electrode region by a technique selected from the group consisting of spin-coating, deposition, and a combination thereof.

21. The semiconductor light-emitting device according to claim 16, wherein said adsorbent material is selected from the group consisting of a metal material, a nano-oxide material, a graphene, an activated carbon, and combinations thereof.

22. The semiconductor light-emitting device according to claim 21, wherein said metal material is selected from the group consisting of Pd, LaNi₅, NdNi₅, CaNi₅, TiNi₅, LaAl₅, LaFe₅, LaCr₅, LaCu₅, LaSi₅, LaSn₅, FeTi, MnTi, CrTi, TiCu, MgZn₂, MgZn₂, NiMg₂, ZrCr₂, ZrMn₂, and combinations thereof.

23. The semiconductor light-emitting device according to claim 21, wherein said nano-oxide material is selected from the group consisting of ZrO₂, CuO, TiO₂, Al₂O₃, and combinations thereof.

24. The semiconductor light-emitting device according to claim 16, wherein said semiconductor structure further includes a current spreading layer formed on at least one selected from the group consisting of said first conductive semiconductor layer and said second conductive semiconductor layer.

25. The semiconductor light-emitting device according to claim 16, wherein said semiconductor structure further includes an insulating protective layer formed on at least one selected from the group consisting of said first conductive semiconductor layer and said second conductive semiconductor layer.
